(19) United States
(12) Patent Application Publication
(10) Pub. No.: US 2026/0106108 A1
(43) Pub. Date: Apr. 16, 2026

(54) SHAPED ION BLOCKER PLATE FOR INDIRECT CCP

(71) Applicant: Applied Materials, Inc., Santa Clara, CA (US)

(72) Inventors: Rupali Sahu, Santa Clara, CA (US); Laxman Vitthalrao Deshmukh, Bangalore (IN); Kallol Bera, Santa Clara, CA (US); Karthikeyan Balaraman, Bangalore (IN); Prahallad Iyengar, Santa Clara, CA (US)

(73) Assignee: Applied Materials, Inc., Santa Clara, CA (US)

(21) Appl. No.: 18/914,654

(22) Filed: Oct. 14, 2024

(51) Int. Cl. H01J 37/32; H01L 21/67

(52) U.S. Cl. CPC H01J 37/32091; H01J 37/3244; H01J 37/32559; H10P 72/0402; H01J 2237/3323

(57) ABSTRACT

Gas distribution apparatus for a semiconductor manufacturing processing chamber, semiconductor manufacturing and methods of using and forming the gas distribution apparatus are described. The gas distribution apparatus has an ion blocker plate with a greater thickness at the outer peripheral region of the ion blocker plate relative to the center of the plate.

### TECHNICAL FIELD

Embodiments of the disclosure are directed to conductively coupled plasma (CCP) sources for semiconductor processing chambers. In particular, embodiments of the disclosure are directed to ion blocker plates for indirect conductively coupled plasma (IDCCP) based semiconductor processing.

### BACKGROUND

In conventional capacitively coupled plasma (CCP) processes, film uniformity is controlled by adjusting the gap between the electrodes, the process chamber (or plasma source) pressure, gas flow, etc. Adjusting the electrode gap and pressure can limit the operational regime and often leads to low throughput.

Additionally, gas flow management can be used to obtain some improvement in the film deposition non-uniformity. However, manipulating the gas flow requires significant addition or alteration to existing hardware.

Therefore, there is a need for capacitively coupled plasma sources with improved plasma uniformity.

### SUMMARY

One or more embodiments of the disclosure are directed to gas distribution apparatus comprising an ion blocker plate. The ion blocker plate has a front surface and a back surface defining a thickness of the ion blocker plate. A plurality of apertures extend through the thickness of the ion blocker plate. One or more of the front surface or back surface is contoured so that the ion blocker plate has a greater thickness at an outer peripheral region of the ion blocker plate.

Additional embodiments of the disclosure are directed to plasma processing chambers comprising a process chamber body, a gas distribution apparatus, and a substrate support. The process chamber body has a bottom wall and at least one sidewall enclosing an interior of the process chamber. The gas distribution apparatus forms a top of the process chamber body. The gas distribution apparatus comprises an RF electrode, an ion blocker plate, an RF isolator and a voltage regulator. The RF electrode has a front surface. The ion blocker plate has a front surface and a back surface defining a thickness of the ion blocker plate. A plurality of apertures extend through the thickness of the ion blocker plate. One or more of the front surface or back surface is contoured so that the ion blocker plate has a greater thickness at an outer peripheral region of the ion blocker plate. The back surface of the ion blocker plate spaced a distance from the front surface of the RF electrode. The RF isolator is between the RF electrode and the ion blocker plate and is configured to prevent direct electrical contact between the RF electrode and the ion blocker plate. The voltage regulator is connected to the ion blocker plate and the RF electrode to polarize one of the ion blocker plate or RF electrode relative to the other of the ion blocker plate and RF electrode. The substrate support within the interior of the process chamber has a support surface configured to support a semiconductor wafer for processing. The support surface is spaced a distance from the front surface of the ion blocker plate to form a process gap.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments described herein are illustrated by way of example and not limitation in the figures of the accompanying drawings in which like references indicate similar elements.

FIG. 1 shows a cross-sectional schematic view of a processing chamber in accordance with one or more embodiments of the disclosure;

FIG. 2 shows a cross-sectional schematic view of a gas distribution apparatus according to one or more embodiments of the disclosure;

FIG. 2A shows a cross-sectional schematic view of a gas distribution apparatus according to one or more embodiments of the disclosure;

FIG. 3 illustrates a partial view of a gas distribution apparatus with contoured ion blocker plate in accordance with one or more embodiments of the disclosure;

FIG. 4A illustrates a schematic view of a contoured ion blocker plate in accordance with one or more embodiments of the disclosure;

FIG. 4B illustrates a schematic view of a contoured ion blocker plate in accordance with one or more embodiments of the disclosure;

FIG. 4C illustrates a schematic view of a contoured ion blocker plate in accordance with one or more embodiments of the disclosure;

FIG. 4D illustrates a schematic view of a contoured ion blocker plate in accordance with one or more embodiments of the disclosure;

FIG. 5 illustrates a cross-sectional schematic view of a gas distribution apparatus with a contoured RF electrode and a flat ion blocker plate according to one or more embodiments of the disclosure; and

FIG. 6 illustrates a cross-sectional schematic view of a gas distribution apparatus with a convex ion blocker plate according to one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

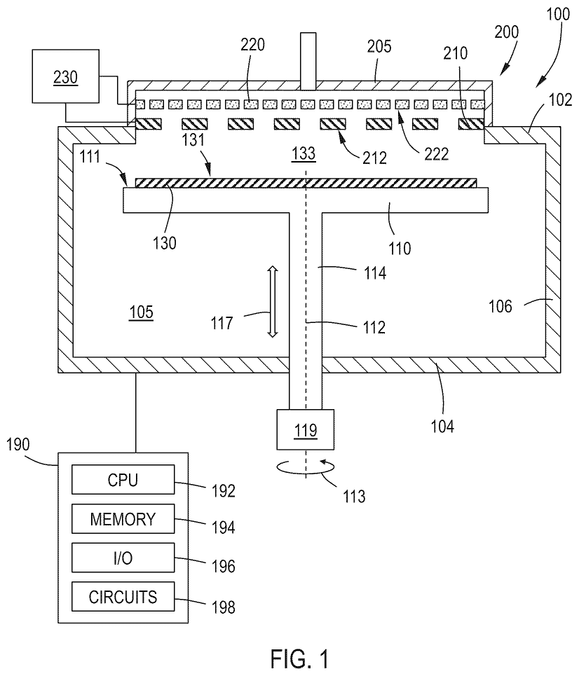

With reference to FIG. 1, one or more embodiments of the disclosure are directed to processing chambers 100 including gas distribution apparatus 200 with an ion blocker plate 210. The processing chamber 100 comprises a top 102, bottom 104 and at least one sidewall 106 enclosing an interior volume 105. The gas distribution apparatus 200 in the illustrated embodiment includes a showerhead 220 with a front surface 222 and a back surface (not numbered) spaced a distance from the ion blocker plate 210. However, this is merely representative of one possible configuration and should not be taken as limiting the scope of the disclosure. In some embodiments, the gas distribution apparatus 200 has an ion blocker plate 210 that acts as both a polarizable component for plasma generation and as a showerhead for uniform gas distribution.

A substrate support 110 is in the interior volume 105 of the processing chamber 100. The substrate support 110 of some embodiments is connected to a support shaft 114. The support shaft 114 can be integrally formed with the substrate support 110 or can be a separate component than the substrate support 100. The support shaft 114 of some embodiments is configured to rotate 113 around a central axis 112 of the substrate support 110. The illustrated embodiment includes a substrate 130 on the support surface 111 of the substrate support 110. The substrate 130 has a substrate surface 131 that faces the front surface 212 of the blocker plate 210 and/or the front surface 222 of the showerhead 220. The space between the support surface 111 and front surface 212 of the ion blocker plate 210 may be referred to as a reaction space 133. In some embodiments, the RF electrode 205 and the showerhead 220 are both polarizable relative to the ion blocker plate 210. In some embodiments, the spacing between the support surface 111 of the substrate support 110 and the front surface 212 of the ion blocker plate 210 is in the range of 1 mm to 15 mm, or in the range of 2 mm to 10 mm, or in the range of 3 mm to 5 mm. In some embodiments, the reaction space 133 has a gap in the range of 1 mm to 15 mm, or in the range of 2 mm to 10 mm, or in the range of 3 mm to 5 mm

In some embodiments, the support shaft 114 is configured to move 117 the support surface 111 closer to or further away from the front surface 222 of the showerhead 220. To rotate 113 or move 117 the support surface 111, the processing chamber of some embodiments includes one or more motors 119 configured for one or more of rotational or translational movement. While a single motor 119 is illustrated in FIG. 1, the skilled artisan will be familiar with suitable motors and suitable arrangements of components to execute the rotational or translational movements.

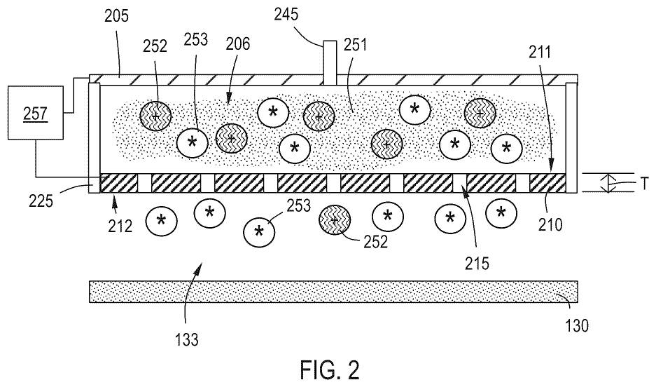

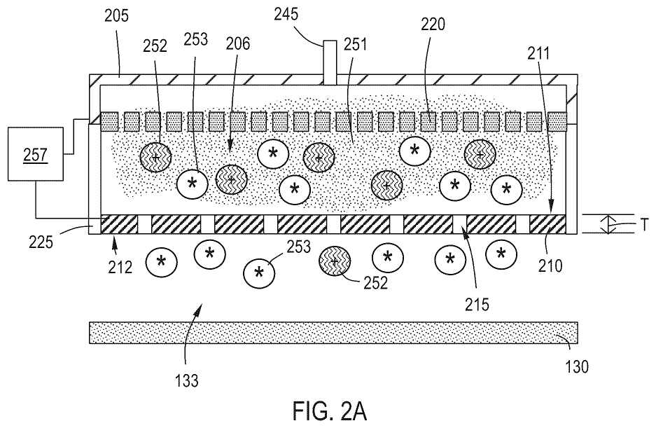

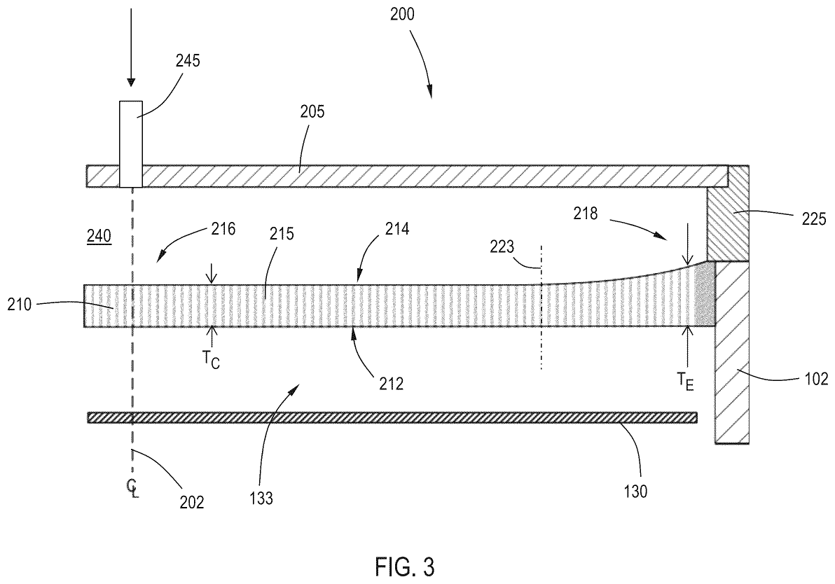

FIGS. 2 and 3 illustrate embodiments of a gas distribution assembly in use with an ion blocker plate 210. A substrate 130 is included in the Figures to show the reaction space 133 and for descriptive purposes. In some embodiments, radicals are provided to the reaction space 133 using the ion blocker plate 210 to decrease the amount of ions present in the plasma 251 from reaching the reaction space 133.

Referring to FIG. 2, in some embodiments, a plasma 251 is generated in the plasma cavity (plasma generation region 206) using a power source 257. The plasma 251 has a first amount of ions 252 and a first amount of radicals 253. The embodiment illustrated in FIG. 2 shows five ions as a first amount of ions 252 in the plasma 251 and one ion as a second amount of ions 252 in the process region 133 after passing through the ion blocker plate 210. The skilled artisan will recognize that this Figure is used to illustrate the operation of one or more embodiments and does not reflect the ratio of ions “filtered” by the ion blocker plate 210.

The plasma 251 can be generated by any suitable technique known to the skilled artisan including, but not limited to, capactively coupled plasma, inductively coupled plasma and microwave plasma. In some embodiments, the plasma 251 is a capacitively coupled plasma generated in the plasma cavity (plasma generation region 206) by applying RF and/or DC power to create a differential between the ion filter plate 210 and the RF electrode 205.

The plasma generated can include any suitable reactive gases in which radicals, rather than ions, are used for reaction. In some embodiments, the plasma gas comprises one or more of molecular oxygen (O₂), molecular nitrogen (N₂), helium (He), molecular hydrogen (H₂), neon (Ne), argon (Ar) or krypton (Kr). The plasma gas can be flowed into the plasma generation region 206 through a gas inlet 245 which may be located in the RF electrode 205 or in a sidewall of the gas distribution apparatus 200.

Generating the plasma 251 according to some embodiments comprises polarizing the ion blocker plate 210 relative to the RF electrode 205. To prevent direct electrical contact between the RF electrode 205 and the ion blocker plate 210, an RF isolator 225 is positioned between the RF electrode 205 and the ion blocker plate 210. The RF isolator 225 can be any suitable material that is non-conductive. In some embodiments, the RF isolator 225 comprises a ceramic material.

The ion blocker plate 210 is polarized to generate the plasma and to prevent or minimize the quantity of ions from the plasma from passing through apertures 215 in the ion blocker plate 210. Polarizing the ion blocker plate 210 decreases the ions 252 passing through the apertures 215 from the first amount to a second amount that is less than the first amount. The ion blocker plate 210 generates a flow of radicals 253 that, according to some embodiments, is substantially free of ions 252. As used in this manner, the term “substantially free of ions” means that the ion composition entering the reaction space 133 is less than or equal to about 10%, 5%, 2%, 1%, 0.5% or 0.1% of the quantity of radicals entering the reaction space 133. In some embodiments, the ion blocker plate 210 is polarized relative to the RF electrode 205 to generate the plasma 251 and removes a portion of, or substantially none of, the first amount of radicals. As used in this manner, the term “substantially none of” means that less than or equal to about 10%, 5%, 2%, 1%, 0.5% or 0.1% of the quantity of ions are removed.

The ion blocker plate 210 of some embodiments decreases the number of ions 252 in the plasma 251 from a first number in the plasma generation region 206 to a second number in the reaction space 133. In some embodiments, the second number is less than or equal to about 50%, 40%, 30%, 20%, 10%, 5%, 2%, 1% or 0.5% of the first number.

Because the ions 252 are charged, the polarized ion blocker plate 210 acts as a barrier to ion 252 passage through the apertures 215. Whereas the radicals 253 are uncharged, the polarized ion blocker plate 210 has a minimal, if any, impact on the movement of the radicals through the apertures 215 so that the radicals 253 can pass through the ion blocker plate 210.

The ion blocker plate 210 can be made of any suitable material having any suitable thickness. In some embodiments, the ion blocker plate 210 comprises aluminum or stainless steel. In some embodiments, the ion blocker plate 210 has a thickness T in the range of about 0.5 mm to about 50 mm, or in the range of about 1 mm to about 25 mm, or in the range of about 2 mm to about 20 mm, or in the range of about 3 mm to about 15 mm, or in the range of about 4 mm to about 10 mm.

The apertures 215 in the ion blocker plate 210 can have a uniform width or can be varied in width. In some embodiments, the apertures 215 have diameters that vary depending on location within the ion blocker plate 210. For example, in some embodiments, the apertures 215 in the ion blocker plate 210 may be larger around the outer peripheral edge of the ion blocker plate 210 than the openings in the center of the ion blocker plate 210. The apertures 215 can be any suitable shape including, but not limited to, circular, oval, slot shaped or irregularly shaped. In some embodiments, the width (or diameter for a circular opening) of any given aperture 215 varies through the thickness T of the ion blocker plate 210. In some embodiments, the apertures 215 are circular and have a diameter in the range of about ⅛″ to about ½″, or in the range of about 3/16″ to about 7/16″, or in the range of about ¼″ to about ⅜″, or about 5/16″. In some embodiments, the apertures 215 are circular and have a diameter in the range of about 0.25 mm to about 13 mm, or in the range of about 0.5 mm to about 12 mm, or in the range of about 1 mm to about 11 mm, or in the range of about 3 mm to about 10 mm, or in the range of about 6 mm to about 9 mm, or about 8 mm.

In some embodiments, the ion blocker plate 210 is polarized relative to the RF electrode 205 using power source 257 (which may also be referred to as a voltage regulator). The voltage regulator is connected to the ion blocker plate 210 and the RF electrode 205 to polarize one of the ion blocker plate 210 or RF electrode 205 relative to the other of the ion blocker plate 210 or RF electrode 205. In some embodiments, the power source 257 is configured to provide a direct current (DC) polarization of the ion blocker plate 210 relative to the showerhead 220 (or the RF electrode 205) in the range of about ±2V to about ±500V, or in the range of about ±5V to about ±400V, or in the range of about ±10V to about ±250V. Stated differently, the ion blocker plate 210 is polarized relative to the showerhead 220 and/or the RF electrode 205 in the range of about 2V to about 500V, or in the range of about 5V to about 400V, or in the range of about 10V to about 250V, with either a positive or negative bias.

FIG. 2A illustrates another embodiment of a gas distribution apparatus 200 in which a showerhead 220 is included between the RF electrode 205 and the ion blocker plate 210. In embodiments of this sort, both the RF electrode 205 and showerhead 220 can be polarized relative to the ion blocker plate 210, or can be maintained at different potentials. In the illustrated embodiment, the RF electrode 205 and showerhead 220 are in electrical contact so that the power source 257 can be connected to both at the same time. In some embodiments, an RF isolator (not shown) is positioned between the RF electrode 205 and the showerhead 220 and the power source 257 (or a separate power source) is connected to the RF electrode 205, ion blocker plate 210 and showerhead 220 to create a potential differential to generate a plasma in the plasma generation region 206. In some embodiments, the plasma 251 in the plasma generation region 206 forms primarily between the showerhead 220 and the ion blocker plate 210 but some plasma 251 can form in the space between the RF electrode 205 and the showerhead 220, or can flow through the openings in the showerhead from the region between the showerhead 220 and the ion blocker plate 210 to the region between the RF electrode 205 and the showerhead 220.

In some embodiments, the plasma gas flows through the gas inlet 245 into the space between the RF electrode 205 and the showerhead 220, and then through the apertures in the showerhead 220 into the space between the showerhead 220 and the ion blocker plate 210. The plasma 251 can ignite in either of the spaces on either side of the showerhead 220 depending on the polarities of the RF electrode 205, ion blocker plate 210 and showerhead 220.

It has been observed that the reaction space 133 often has an edge high flux of radicals and ions, relative to the center of the reaction space 133 (i.e., over the center of the wafer being processed. This radial non-uniformity can result in different film characteristics at the outer edges of the wafer. Accordingly, one or more embodiment of the disclosure relates to ion blocker plates for indirect CCP (IDCCP) based processing. One or more embodiments of the disclosure advantageously provide shaped ion blocker plates and methods for shaping ion blocker plates to enhance plasma uniformity over the wafer.

Some embodiments of the disclosure provide a process chamber configuration that improves processing uniformity over the area of a wafer for a given set of operating conditions. Currently, the uniformity in CCP processes is controlled by adjusting the electrode gap, pressure, gas flow, etc. Adjusting the electrode gap and pressure can limit the operational regime and often leads to low throughput. Manipulating the gas flow requires significant addition or alteration of hardware. On the contrary, ion blocker plate shape can be relatively easily customized to allow uniform plasma distribution over the wafer for a given process recipe. Some embodiments of the disclosure, assuming that plasma in the electrode gap is non-uniform, provides ion blocker plates shaped so that the plasma transferred from the electrode gap to the wafer gap is uniform.

FIG. 3 illustrates the gas distribution apparatus portion of an IDCCP process chamber. The chamber lid 102 and a substrate 130 are included for reference and descriptive purposes. The gas distribution apparatus 200 illustrated has three major components: RF electrode 205, grounded ion blocker plate 210, and a RF isolator 225, with the wafer 130 for reference. The RF isolator 225 of some embodiments contacts the outer edges of the RF electrode 205 and the ion blocker plate 210. A plasma is established in the gap 240 between the RF electrode 205 and the ion blocker plate 210. This is also referred to as the electrode gap. There are apertures 215 or holes in the ion blocker plate 210 that selectively block ions and allow radicals to pass through to the gap (reaction space 133) between the ion blocker plate 210 and the wafer 130. This is also referred to as the wafer gap. If the plasma is non-uniform in the electrode gap, an ion blocker plate 210 designed as a flat plate will allow that non-uniformity to be transferred to the wafer gap. The inventors have surprisingly found that using a shaped ion-blocker plate, plasma distribution over the wafer can be efficiently controlled to achieve uniform processing.

Without being bound by any particular theory of operation, it is believed that a shaped ion blocker plate 210 of some embodiments, there is a higher plate thickness adjacent to the region with high plasma density. Large plate thickness increases the hole (aperture 215) surface area that the plasma needs to interact with, thereby increasing the surface losses. This reduces the plasma density transferred to the wafer gap and hence improves uniformity in plasma processing. The embodiment illustrated in FIG. 3, is merely for descriptive purposes and should not be taken as limiting the scope of the disclosure. The slope and relative dimensions of the components are not to scale but are exaggerated for discussion.

Generally, the gap 240 between the RF electrode 205 and the ion blocker plate 210 is controlled to generate a stable plasma. The ion blocker plate thickness in some embodiments is determined by the structural rigidity requirements. For example, larger diameter ion blocker plates 210 may be thicker overall for structural integrity. The diameter of the holes (apertures 215) in the ion blocker plate 210 in some embodiments is on the order of the sheath width to block the ions. The gap between the ion blocker plate 210 and wafer 130 (or support surface 111 of the substrate support 110) of some embodiments minimizes or eliminates the appearance of a film pattern on the substrate 130 indicative of the aperture pattern on the ion blocker plate 210. Some embodiments of the disclosure advantageously provide shaped ion blocker plates that improve uniformity for various process conditions. Some embodiments advantageously provide shaped ion blocker plates that enhance the structural rigidity of the plate.

Some embodiments of the disclosure provide designs for ion blocker plates for a given process recipe. Transmission of plasma species through the ion blocker plate is very sensitive to the plate thickness, and the inventors have found that small variations in plate thickness can prove to be quite helpful in improving uniformity. Additionally, embodiments of the disclosure can be used with any indirect or remote plasma process; i.e., a process where the plasma is generated in a region away from the substrate surface. In some embodiments, in which the non-uniform plasma distributions is other than the edge-high described here, the ion blocker plate would be shaped differently. In some embodiments, an ion blocker plate is shaped so that the thickness in the region of high plasma density is increased in the range of 25-75% of the observed non-uniformity. For example, if a process shows a torus type high ion density, the ion blocker plate would be made to have a ring of thicker material around the central axis of the ion blocker plate.

Still referring to FIG. 3, one or more embodiments of the disclosure are directed to gas distribution apparatus 200. As will be readily understood by the skilled artisan, half of the apparatus is illustrated with the unshown portion being a mirror image across center line 202. The gas distribution apparatus 200 includes an ion blocker plate 210 having a front surface 212 and a back surface 214 that define the thickness of the ion blocker plate 210. A plurality of apertures 215 extend through the thickness of the ion blocker plate 210. One or more of the front surface 212 or the back surface 214 of the ion blocker plate 210 is contoured, or shaped, so that the ion blocker plate 210 as a greater thickness at the outer peripheral region 218 of the ion blocker plate 210 relative to the center region 216 of the ion blocker plate 210.

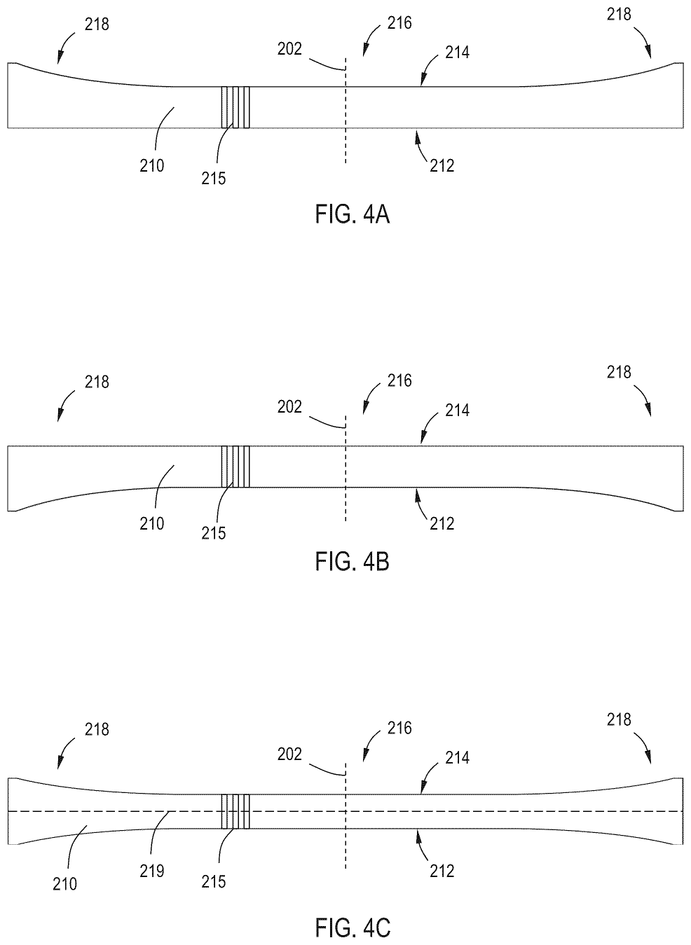

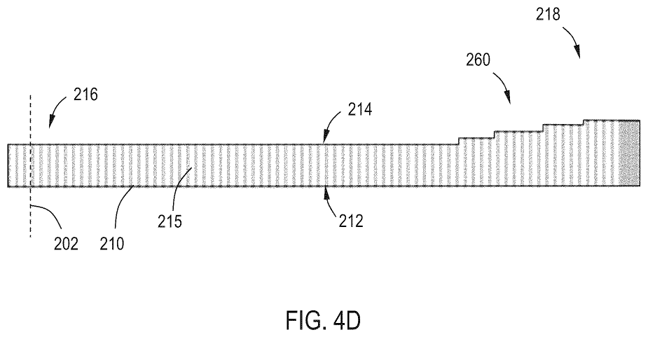

FIG. 4A illustrates an embodiment of the ion blocker plate 210 in which the back surface 214 is contoured, or shaped, and the front surface 212 is substantially flat. As used in this specification and the appended claims, the term “substantially flat” means that the stated surface is flat to a normally acceptable manufacturing tolerance. FIG. 4B illustrates an embodiment of an ion blocker plate 210 in which the front surface 212 is contoured, or shaped, and the back surface 214 is substantially flat. FIG. 4C illustrates an embodiment of an ion blocker plate 210 in which both the front surface 212 and back surface 214 are contoured, or shaped. For descriptive purposes, the embodiments illustrated in FIGS. 4A through 4C include three apertures 215. However, the skilled artisan will recognize that there will be more than three apertures 215 across the surfaces of the ion blocker plate 210.

Referring again to FIG. 3, in some embodiments, when one of the front surface 212 or back surface 214 of the ion blocker plate 210 is substantially flat, the apertures 215 extending through the thickness of the ion blocker plate 210 are perpendicular to the flat surface. When both the front surface 212 and back surface 214 of the ion blocker plate 210 are contoured, the apertures 215 extend through the thickness of the ion blocker plate 210 perpendicular to a mid-plane 219 (as shown in FIG. 4C) between the front surface 212 and the back surface 214.

In some embodiments, the apertures 215 are evenly spaced across the ion blocker plate 210. In some embodiments, the apertures 215 are spaced in a spiral or a non-uniform pattern across the ion blocker plate 210.

In some embodiments, the thickness T_{E} of the ion blocker plate 210 at the outer peripheral region 218 is greater than or equal to 1 mm greater than the thickness T_{C} of the ion blocker plate 210 at the center region 216 of the ion blocker plate 210. In some embodiments, the thickness T_{E} at the outer peripheral region 218 is greater than the thickness T_{C} at the center region 216 by an amount greater than or equal to 0.5 mm, 0.75 mm, 1 mm, 1.25 mm, 1.5 mm, 1.75 mm or 2 mm. In some embodiments, the thickness T_{E} of the ion blocker plate 210 at the outer peripheral region 218 is greater than or equal to 5 mm, 6 mm, 7 mm, 8 mm, 9 mm or 10 mm. In one or more embodiments the thickness T_{C} at the center region 216 of the ion blocker plate 210 is 6 mm and the thickness T_{E} at the outer peripheral region 218 of the ion blocker plate 210 is 7 mm. In some embodiments, thickness T_{E} at the outer peripheral region 218 of the ion blocker plate 210 is in the range of greater than 0% to 50%, or in the range of greater than 0.5% to 45%, or in the range of 1% to 40%, or in the range of 5% to 25% greater than the thickness T_{C} at the center region 216 of the ion blocker plate 210.

The shape of the contoured surface can vary depending on, for example, the ion and/or radical flux adjacent the substrate 130 on the front surface 212 side of the ion blocker plate 210. In some embodiments, the contour of one or more of the front surface 212 or back surface 214 is a concave shape. In some embodiments, as shown in the Figures, the contour is a smooth transition from the thickness T_{C} at the center region 216 of the ion blocker plate 210 to the thickness T_{E} at the outer peripheral region 218 of the ion blocker plate 210. The transition 223 from the flat surface at the center region 216 of the back surface 214 of the ion blocker plate 210 in some embodiments begins at a distance from the center 202 of the ion blocker plate 210 that is greater than or equal to 50%, 60%, 70%, 75%, 80%, 85% or 90% of the radius of the ion blocker plate 210.

In some embodiments, as shown in FIG. 4D, the contour, or shape, of the one or more of the front surface 212 or back surface 214 is in steps 260. In the illustrated embodiment, there are four steps 260, with each step of about equal height and width. However, the steps 260 can have independent heights (increasing the thickness of the ion blocker plate 210) and widths.

The ion blocker plate 210 of some embodiments improves the uniformity of the plasma density adjacent to the front surface 212 of the ion blocker plate 210. In some embodiments, the non-uniformity adjacent the front surface 212 between a center 216 of the ion blocker plate 210 and the outer peripheral region 218 of the ion blocker plate 210 is less than or equal to 25%, 20%, 15%, or 10%.

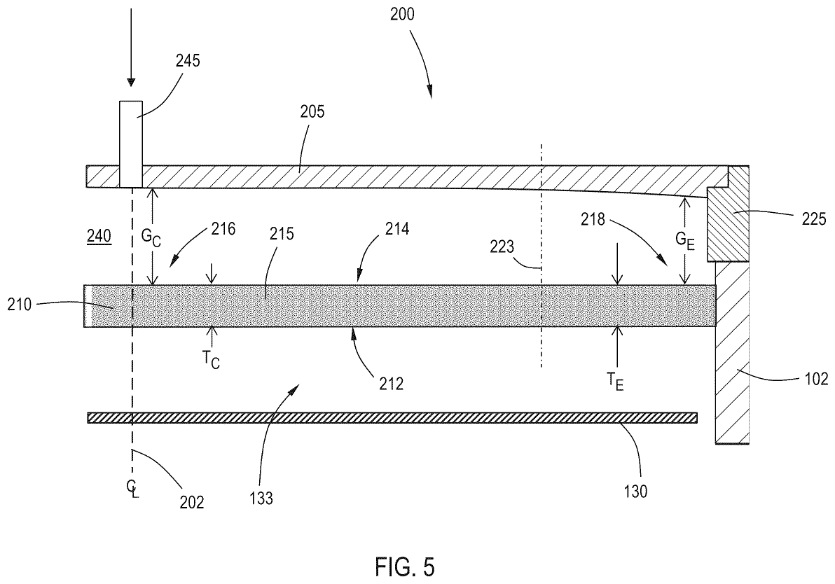

In one or more embodiments, the spacing between the RF electrode 205 (and/or showerhead 220) and the ion blocker plate 210 varies from the center region 216 of the ion blocker plate 210 to the outer peripheral region 218 of the ion blocker plate 210. FIGS. 2 through 4D describe changes in the thickness of the ion blocker plate 210. FIG. 5 illustrates another embodiment in which the spacing between the RF electrode 205 and the ion blocker plate 210 varies. In this embodiment, the ion blocker plate 210 is a flat body and the RF electrode 205 is shaped so that the gap G_{C} between the RF electrode 205 and the ion blocker plate 210 at the center region 216 of the ion blocker plate 210 is greater than the gap G_{E} between the RF electrode 205 and the ion blocker plate 210 at the outer peripheral region 218 of the ion blocker plate 210. In some embodiments, the gap G_{C} at the center region 216 is greater than the gap G_{E} at the outer peripheral region 218 by an amount greater than or equal to 0.5 mm, 0.75 mm, 1 mm, 1.25 mm, 1.5 mm, 1.75 mm or 2 mm.

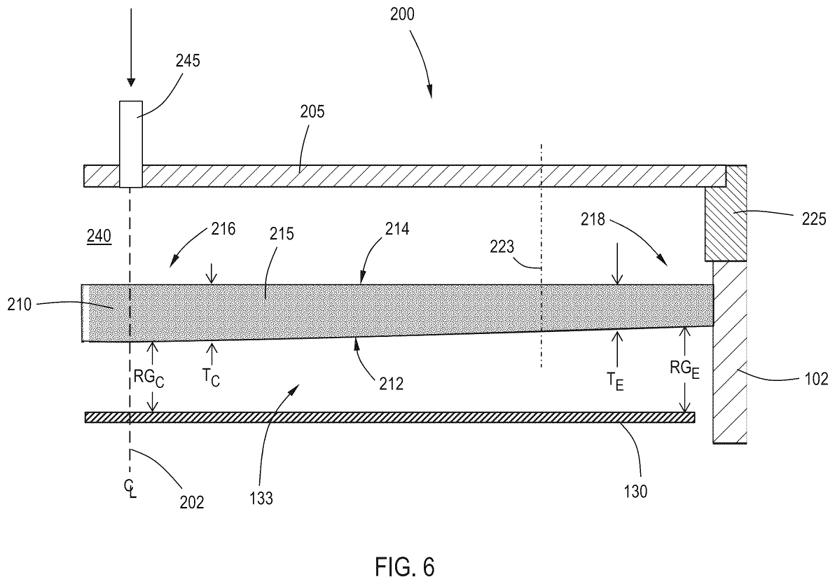

FIG. 6 illustrates another embodiment of the disclosure in which the ion blocker plate 210 has a greater thickness T_{C} at the center region 216 than the thickness T_{E} at the outer peripheral region 218. Embodiments of this sort, where the ion blocker plate 210 has a convex shaped front surface 212, may be useful where the plasma generated in the gap 240 has a higher ion density at the center of the gap 240 than at the outer peripheral edge of the gap 240. The convex shape of this embodiment results in a different reaction space gap RG_{C} at the center region 216 than the reaction space gap RG_{E} at the outer peripheral region 218 of the ion blocker plate 210.

In some embodiments, the thickness T_{E} of the ion blocker plate 210 at the outer peripheral region 218 is greater than or equal to 1 mm less than the thickness T_{C} of the ion blocker plate 210 at the center region 216 of the ion blocker plate 210. In some embodiments, the thickness T_{E} at the outer peripheral region 218 is less than the thickness T_{C} at the center region 216 by an amount greater than or equal to 0.5 mm, 0.75 mm, 1 mm, 1.25 mm, 1.5 mm, 1.75 mm or 2 mm. In some embodiments, the thickness T_{C} of the ion blocker plate 210 at the center region 216 is greater than or equal to 5 mm, 6 mm, 7 mm, 8 mm, 9 mm or 10 mm. In one or more embodiments the thickness T_{C} at the center region 216 of the ion blocker plate 210 is 7 mm and the thickness T_{E} at the outer peripheral region 218 of the ion blocker plate 210 is 6 mm. In some embodiments, the thickness T_{E} at the outer peripheral region 218 of the ion blocker plate 210 is in the range of greater than 0% to 50%, or in the range of greater than 0.5% to 45%, or in the range of 1% to 40%, or in the range of 5% to 25% smaller than the thickness T_{C} at the center region 216 of the ion blocker plate 210.

The shape of the contoured surface can vary depending on, for example, the ion and/or radical flux adjacent the substrate 130 on the front surface 212 side of the ion blocker plate 210. In some embodiments, the contour of one or more of the front surface 212 or back surface 214 is a convex shape. In some embodiments, as shown in the FIG. 6, the contour is a smooth transition from the thickness T_{C} at the center region 216 of the ion blocker plate 210 to the thickness T_{E} at the outer peripheral region 218 of the ion blocker plate 210. In some embodiments, there is a transition (not shown) from a flat portion, either at the center region 216 or the outer peripheral region 218 to the convex portion. The transition from a flat surface of the front surface 212 of the ion blocker plate 210, in some embodiments, begins at a distance from the center 202 of the ion blocker plate 210 that is greater than or equal to 50%, 60%, 70%, 75%, 80%, 85% or 90% of the radius of the ion blocker plate 210.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A gas distribution apparatus comprising:
an ion blocker plate having a front surface and a back surface defining a thickness of the ion blocker plate, a plurality of apertures extending through the thickness of the ion blocker plate, one or more of the front surface or back surface contoured so that the ion blocker plate has a greater thickness at an outer peripheral region of the ion blocker plate.

2. The gas distribution apparatus of claim 1, wherein the back surface of the ion blocker plate is contoured and the front surface is substantially flat.

3. The gas distribution apparatus of claim 1, wherein the front surface of the ion blocker plate is contoured and the back surface is substantially flat.

4. The gas distribution apparatus of claim 1, wherein both the front surface and the back surface of the ion blocker plate are contoured.

5. The gas distribution apparatus of claim 1, wherein when one of the front surface or back surface of the ion blocker plate is substantially flat, the apertures extending through the thickness of the ion blocker plate are perpendicular to the flat surface, and when both the front surface and back surface of the ion blocker plate are contoured, the apertures extending through the thickness of the ion blocker plate are perpendicular to a mid-plane between the front surface and back surface.

6. The gas distribution apparatus of claim 5, wherein the apertures are evenly spaced across the ion blocker plate.

7. The gas distribution apparatus of claim 1, wherein the thickness of the ion blocker plate at the outer peripheral region is greater than or equal to 1 mm greater than the thickness of the ion blocker plate at a center of the ion blocker plate.

8. The gas distribution apparatus of claim 7, wherein the center of the ion blocker plate has a thickness of 6 mm and the outer peripheral region has a thickness of 7 mm.

9. The gas distribution apparatus of claim 1, wherein the contour of one or more of the front surface or back surface is a concave shape.

10. The gas distribution apparatus of claim 9, wherein the contour is a smooth transition from the thickness at a center of the ion blocker plate to the thickness at the outer peripheral region of the ion blocker plate, the transition beginning at a distance from the center of the ion blocker plate greater than or equal to 75% of a radius of the ion blocker plate.

11. The gas distribution apparatus of claim 1, wherein the contour of the one or more of the front surface or back surface is stepped.

12. The gas distribution apparatus of claim 1, further comprising
an RF electrode spaced a distance from the back surface of the ion blocker plate;
an RF isolator between the RF electrode and the ion blocker plate configured to prevent direct electrical contact between the RF electrode and the ion blocker plate; and
a voltage regulator connected to the ion blocker plate and the RF electrode to polarize one of the ion blocker plate or RF electrode relative to the other of the ion blocker plate or RF electrode.

13. The gas distribution apparatus of claim 1, wherein a plasma density non-uniformity adjacent the front surface between a center of the ion blocker plate and the outer peripheral region of the ion blocker plate is less than or equal to 20%.

14. A plasma processing chamber comprising:
a process chamber body having a bottom wall and at least one sidewall enclosing an interior of the process chamber;
a gas distribution apparatus forming a top of the process chamber body, the gas distribution apparatus comprising,
an RF electrode having a front surface,
an ion blocker plate having a front surface and a back surface defining a thickness of the ion blocker plate, a plurality of apertures extending through the thickness of the ion blocker plate, one or more of the front surface or back surface contoured so that the ion blocker plate has a greater thickness at an outer peripheral region of the ion blocker plate, the back surface of the ion blocker plate spaced a distance from the front surface of the RF electrode,
an RF isolator between the RF electrode and the ion blocker plate configured to prevent direct electrical contact between the RF electrode and the ion blocker plate, and
a voltage regulator connected to the ion blocker plate and the RF electrode to polarize one of the ion blocker plate or RF electrode relative to the other of the ion blocker plate or RF electrode; and
a substrate support within the interior of the process chamber, the substrate support having a support surface configured to support a semiconductor wafer for processing, the support surface spaced a distance from the front surface of the ion blocker plate to form a process gap.

15. The plasma processing chamber of claim 14, wherein the ion blocker plate acts as an electrode for formation of a plasma between the RF electrode and the ion blocker plate, and acts as a showerhead for uniform gas distribution into the process gap.

16. The plasma processing chamber of claim 14, wherein the thickness of the ion blocker plate at the outer peripheral region is greater than or equal to 1 mm greater than the thickness of the ion blocker plate at a center of the ion blocker plate.

17. The plasma processing chamber of claim 16, wherein the back surface of the ion blocker plate is contoured, and the front surface is substantially flat.

18. The plasma processing chamber of claim 16, wherein the front surface of the ion blocker plate is contoured, and the back surface is substantially flat.

19. The plasma processing chamber of claim 16, wherein both the front surface and the back surface of the ion blocker plate are contoured.

20. The plasma processing chamber of claim 17, wherein the contour is a smooth transition from the thickness at a center of the ion blocker plate to the thickness at the outer peripheral region of the ion blocker plate, the transition beginning at a distance from the center of the ion blocker plate greater than or equal to 75% of a radius of the ion blocker plate.
